(19) United States
(12) Patent Application Publication
(10) Pub. No.: US 2019/0007005 A1
(43) Pub. Date: Jan. 3, 2019

(54) CRYSTAL AMPLIFIER WITH RESISTIVE DEGENERATION

(71) Applicant: SILICON LABORATORIES INC., Austin, TX (US)

(72) Inventor: TIAGO MARQUES, Austin, TX (US)

(21) Appl. No.: 15/639,137

(22) Filed: Jun. 30, 2017

(51) Int. Cl. H03F 3/16; H01L 27/07

(52) U.S. Cl. CPC H03F 3/16; H03F 3/45179; H01L 27/0727

(57) ABSTRACT

A crystal amplifier for driving a crystal to oscillate at a resonant frequency including a current source, an amplifier, and at least one degeneration resistor. The amplifier has an input coupled to an amplifier input node and has an amplifier output current path coupled the amplifier output node. Each degeneration resistor is coupled in series with the amplifier output current path. The current source provides a core bias current through the amplifier output current path and through each degeneration resistor to a reference node. The resistance of each degeneration resistor may be selected to minimize a frequency shift over an operating temperature range while maintaining at least one operating parameter within predetermined operating limits, or can be selected based on a crystal type. Each degeneration resistor may be fixed or adjustable.

### CROSS REFERENCE TO RELATED APPLICATION(S)

This application is related to the following U.S. patent applications which are filed concurrently herewith and which are hereby incorporated by reference in their entireties for all intents and purposes.

| ATTORNEY | | | |
|---|---|---|---|
| DOCKET | SERIAL | FILING | |
| NUMBER | NO. | DATE | TITLE |
| SLL.0107 | — | — | CRYSTAL AMPLIFIER WITH |
| | | | ADDITIONAL HIGH |
| | | | GAIN AMPLIFIER |
| | | | CORE TO OPTIMIZE STARTUP |
| | | | OPERATION |
| SLL.0109 | — | — | CRYSTAL DRIVER CIRCUIT |
| | | | WITH CORE AMPLIFIER |
| | | | HAVING UNBALANCED |
| | | | TUNE CAPACITORS |
| SLL.0110 | — | — | CRYSTAL DRIVER CIRCUIT |
| | | | CONFIGURABLE FOR DAISY |
| | | | CHAINING |
| SLL.0111 | — | — | CRYSTAL DRIVER CIRCUIT |
| | | | WITH EXTERNAL |
| | | | OSCILLATION SIGNAL |
| | | | AMPLITUDE CONTROL |

### BACKGROUND OF THE INVENTION

### Field of the Invention

The present invention relates in general to crystal oscillators, and more particularly, to a crystal amplifier for a crystal oscillator with resistive degeneration for reducing frequency drift.

### Description of the Related Art

A crystal oscillator uses the mechanical resonance of a crystal to create an electrical sinusoidal signal having a precise frequency. The crystal oscillator includes a crystal amplifier providing a “negative” resistance that cancels losses of the crystal to establish and maintain oscillation. In certain configurations, the crystal amplifier may include an N-channel MOS (NMOS) or a complementary MOS (CMOS) amplifier having an input and output for coupling across the crystal. The crystal may be modeled as a series combination of a motional capacitance, inductance, and resistance, and the crystal amplifier may be modeled as a negative resistance. The negative resistance of the crystal amplifier is designed to cancel losses of the crystal to establish and maintain oscillation.

The crystal amplifier has an input and an output for coupling across the crystal, and further includes a current source that generates a core bias current to establish the gain of the amplifier. During steady state operation, the core bias current is set at a steady state current level to obtain or otherwise maintain a target characteristic (other than the precise frequency), such as the signal level at the input or output of the amplifier. The steady state current level may be predetermined for a known crystal based on the crystal type and specification. Alternatively, the core bias current may be determined during operation using an automatic gain control (AGC) process or the like.

The determined steady state current level, however, may be suitable for a given temperature value or temperature range. As the temperature rises, the amplitude of the oscillating signal decreases and the frequency also changes. Changes in temperature have an effect on the operation of the crystal as well as the crystal amplifier. At certain increments of temperature change, the AGC process may be re-run to adjust the core bias current to return the amplitude of the oscillating signal back to the target value. The AGC maintains the same amplitude to optimize certain operating parameters, such as the phase noise, power supply rejection (PSR), and reverse PSR. A change in temperature by itself changes the distortion level of the crystal amplifier and the change in distortion causes a change in frequency. Also, the change in current in response to the AGC optimization causes a change in distortion level which leads to an additional change in frequency. Described another way, when the temperature and core bias current are changed, the average impedance looking into the amplifier output from the crystal changes in a manner equivalent to a shift in the load capacitance, which causes a frequency shift. Although these changes may be relatively small, in some cases the total allowed temperature drift is below 20 parts-per-million (ppm) or even lower. This drift needs to account for crystal and amplifier induced frequency variation, ideally the amplifier caused variation should be minimal to account for the expected changes in the crystal itself.

### SUMMARY OF THE INVENTION

A crystal amplifier for driving a crystal to oscillate at a resonant frequency according to one embodiment includes a current source, an amplifier, and at least one degeneration resistor. The amplifier has an input coupled to an amplifier input node and has an amplifier output current path coupled to an amplifier output node. The amplifier may be configured as a CMOS amplifier or an NMOS amplifier including a bias resistor coupled between the amplifier input and output nodes. Each degeneration resistor is coupled in series with the amplifier output current path. The current source provides a core bias current through the amplifier output current path and through each degeneration resistor to a reference node.

The resistance of each degeneration resistor can be selected based on a crystal type. The resistance of each degeneration resistor may be selected to minimize a frequency shift of an oscillating signal of the crystal over an operating temperature range while maintaining at least one operating parameter within predetermined operating limits. Each degeneration resistor may be adjustable, and a controller may be provided to select a resistance of each degeneration resistor. A memory may be included for storing at least one digital value accessible by the controller for selecting the resistance of each degeneration resistor. The controller may be a digital state machine.

Each degeneration resistor may include multiple resistors and multiple switches for selecting a resistance between first and second resistor terminals of each degeneration resistor. Various switched resistor configurations are contemplated. The amplifier may be a CMOS type including two degeneration resistors. Alternatively, the amplifier core may be an NMOS type including a single degeneration resistor.

An electronic circuit according to one embodiment includes a crystal and a crystal amplifier for driving the crystal to oscillate at a resonant frequency. The crystal amplifier includes an amplifier input node coupled to a first terminal of the crystal and an amplifier output node coupled to a second terminal of the crystal. The crystal amplifier further includes an amplifier, at least one degeneration resistor, and a current source. The amplifier has an input coupled to the amplifier input node and has an amplifier output current path coupled to the amplifier output node. Each of one or more degeneration resistors is coupled in series with the amplifier output current path. The current source provides a core bias current through the amplifier output current path and through each degeneration resistor to a reference node. Each degeneration resistor may have a resistance that minimizes a frequency shift of an oscillating signal of the crystal over an operating temperature range.

A method of driving a crystal to oscillate at a resonant frequency according to one embodiment includes providing an amplifier input node and an amplifier output node for coupling across the crystal, providing an amplifier having an input coupled to the amplifier input node and having an amplifier output current path coupled to the amplifier output node, providing at least one degeneration resistor coupled in series with the amplifier output current path, and providing a core bias current through the amplifier output current path and through the at least one degeneration resistor to a reference node.

The method may include providing each degeneration resistor with a resistance that can be selected based on a crystal type. The method may include providing each degeneration resistor with a resistance that minimizes a frequency shift of an oscillating signal of the crystal over an operating temperature range while maintaining at least one operating parameter within predetermined operating limits. The method may include providing at least one adjustable degeneration resistor and providing a controller that selects a resistance of each degeneration resistor. The method may include storing at least one digital value accessible by the controller for selecting the resistance of each degeneration resistor. The method may include providing multiple resistors and switches and controlling the switches for selecting a resistance between the first and second resistor terminals for each degeneration resistor. The method may include selecting a resistance of each degeneration resistor to minimize a frequency shift of an oscillating signal of the crystal over an operating temperature range while maintaining phase noise degradation within an allowable range. The method may include selecting a resistance of each degeneration resistor to minimize a frequency shift of the oscillating signal of the crystal over an operating temperature range while maintaining degradation of power supply rejection within an allowable range.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a simplified block diagram of a transceiver including a crystal oscillator (XO) system implemented according to one embodiment of the present invention.

FIG. 2 is a simplified block diagram of the XO system of FIG. 1 incorporating a single crystal amplifier and supporting circuitry.

FIG. 3 is a schematic and block diagram of the crystal amplifier of FIG. 2 implemented according to one embodiment of the present invention shown coupled to the crystal and the controller, and further including a select circuit, a level detector, and a memory.

FIG. 4 is a schematic diagram of an alternative amplifier that may replace the amplifier shown in FIG. 3.

FIG. 5 is a schematic diagram of R1 according to one embodiment of the present invention in which R1 is programmable or otherwise adjustable.

FIG. 6 is a schematic diagram of R2 implemented according to one embodiment of the present invention in which R2 is programmable or otherwise adjustable.

FIG. 7 is a flowchart diagram of a simplified test procedure of the crystal oscillator of FIG. 3 for determining resistance values for the degeneration resistors R1 and R2 of the CMOS amplifier for one or more different crystals according to one embodiment of the present invention (which also applies to a single resistor for an NMOS amplifier core).

### DETAILED DESCRIPTION

The inventor has recognized the need to reduce distortion which is a major contributor to the frequency drift over temperature with or without AGC optimization. The inventor has therefore developed a crystal amplifier with resistive degeneration that reduces the distortion and frequency drift with temperature changes. When the crystal amplifier output is close to the rails, the amplifying devices get close to the triode region reducing their output impedance, and during that part of the oscillation cycle the impedance as applied to the crystal reduces, resulting in a reduction of average impedance. The reduction of average impedance provided to the crystal causes a change in the average load capacitance, which leads to a change in frequency. Adding degeneration resistance causes the impedance deltas to be smaller, thus minimizing the frequency deviation. The degeneration resistors tend to lower the gain slightly, which causes some variation of certain operating parameters of the crystal amplifier, including phase noise, power supply rejection (PSR), and reverse PSR. The resistive values of the degeneration resistors are selected to maximize the reduction of signal distortion, thus minimizing the frequency shift, while reducing degradation of the operating parameters by an acceptable amount.

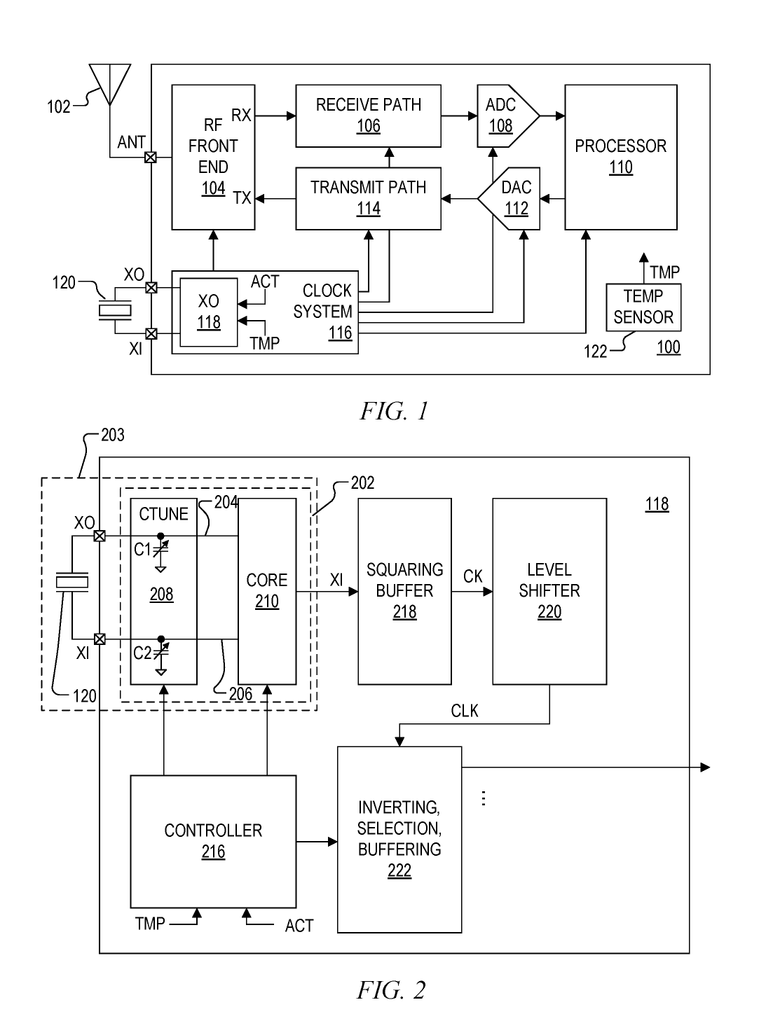

FIG. 1 is a simplified block diagram of a transceiver 100 including a crystal oscillator (XO) system 118 implemented according to one embodiment of the present invention. The illustrated transceiver 100 is shown in generalized form for any of various wireless communication applications, such as Bluetooth®, Zigbee, Wi-Fi, etc. Other functional circuit blocks and circuits may be included for particular applications, but are not shown as not necessary for a full and complete understanding of the present invention. The transceiver 100 may be implemented on an integrated circuit (IC) or semiconductor chip or the like, which may be mounted on a printed circuit board (PCB) (not shown), a module (not shown), or the like as part of an electronic system. It is noted that the XO system 118 may be integrated on a separate IC or semiconductor chip or the like either alone or as part of a separate clock system (e.g., shown as a clock system 116).

The electronic system incorporating the transceiver 100 is any one of various configurations, such as a communication device (hand-held, mobile, stationary, etc.), a computer system (laptop, desktop, server system, etc.), a computer peripheral device (e.g., printer, router, etc.), or any other devices that may be networked together via wired and/or wireless communications. The present disclosure contemplates the use of the transceiver 100 incorporated within a device that may be part of a suite of components of an Internet of Things (IoT) platform or the like. The components or devices may be powered from an external source (e.g., AC outlet or the like), or may be battery-operated. Although the present invention is illustrated within a wireless communication system, it is understood that the present invention is not limited to wireless communications and may be used in any application that uses a crystal oscillator.

The transceiver 100 includes a radio frequency (RF) front end 104 coupled to an antenna 102 via an antenna pin ANT (or other appropriate antenna interface) for receiving and transmitting RF signals. The RF front end 104 has a receive (RX) output coupled to the input of a receive path 106, which processes received signals and which provides a processed analog baseband signal at its output for conversion to digital format by an analog to digital converter (ADC) 108. The ADC 108 provides digital baseband signals to a processor 110, which further processes the digital baseband signals according to the particular application. The processor 110 also encapsulates and provides digital baseband signals for transmission, which are converted to analog format by a digital to analog converter (DAC) 112, which has an output provided to an input of a transmit path 114. The output of the transmit path 114 is provided to a transmit (TX) input of the RF front end 104, which ultimately transmits the information via the antenna 102.

The particular details of each of the functional blocks are beyond the scope of the present disclosure. In one embodiment, for example, the RF front end 104 may include one or more mixers that downconvert received RF signals to an intermediate frequency (IF), or that directly convert received RF signals to baseband signals, which are further processed by the receive path 106. In an IF configuration, the receive path 106 further includes one or more mixers or the like for downconverting IF signals to the baseband signals. In either case, the receive path 106 further includes amplifiers (e.g., programmable gain amplifiers or PGAs), filters (e.g., low-pass filters or LPFs), peak detectors, and other supporting circuitry for isolating and processing the baseband signals for digital conversion for further processing by the processor 110. The transmit path 114 includes similar functions for processing an analog baseband signal from the DAC 112 for transmission by the RF front and 104 to external devices or components.

The transceiver 100 further includes the clock system 116 incorporating the XO system 118 which is coupled to an external crystal 120 via an amplifier output pin XO and an amplifier input pin XI. The clock system 116 generally develops one or more clock signals for use by the various functional blocks of the transceiver 100. The present disclosure primarily concerns the XO system 118 including a crystal amplifier for driving the crystal 120 to develop an oscillation signal used for developing one or more clock signals. Although not shown, the clock system 116 may include additional crystal amplifiers, which may include high frequency and/or low frequency variations, along with one or more resistor-capacitor (RC) oscillators and the like. In one embodiment, the XO system 118 is maintained in a power-down or standby mode when not being used. In the illustrated configuration, the transceiver 100 and/or the clock system 116 provides an activation signal ACT which is asserted to activate or enable the XO system 118 and negated to place the XO system 118 into the standby mode.

Various methods may be used for determining and/or reporting the temperature of the IC and/or the semiconductor chip incorporating the transceiver 100 and/or the electronic system. The electronic system may include a temperature sensor or the like (not shown) that provides a temperature value to the transceiver 100 via an appropriate interface or via other communicating method. In another embodiment, the transceiver 100 includes a temperature sensor 122 providing a temperature value TMP indicative of the IC or ambient temperature. In yet another embodiment, the crystal case can include a thermistor that the electronic system may drive, measure and extract crystal temperature. The temperature value TMP is shown provided to the XO system 118. In an alternative embodiment, the XO system 118 does not receive a temperature indication but instead the transceiver 100 or the electronic system itself handles issues related to temperature.

FIG. 2 is a simplified block diagram of the XO system 118 incorporating a single crystal amplifier 202 and supporting circuitry. The crystal 120 is coupled between the XO and XI pins of the transceiver 100, in which XO is internally coupled an amplifier output node 204 and XI is internally coupled to an amplifier input node 206. As used herein, “XO” generally refers to the XO pin and/or the amplifier output node 204 and “XI” generally refers to the XI pin and/or the amplifier input node 206. It is noted that the combination of the crystal amplifier 202 and the crystal 120 is referred to as a crystal oscillator 203. The crystal amplifier 202 includes a tuning capacitor (CTUNE) circuit 208 and an amplifier core 210, which are both coupled to the amplifier input and output nodes 204 and 206. The CTUNE circuit 208 includes a first adjustable capacitor C1 coupled between the amplifier output node 204 and a reference node and a second adjustable capacitor C2 coupled between the amplifier input node 206 and the reference node. The reference node develops a suitable positive, negative or zero voltage level, such as ground (GND). The controller 216 receives the ACT signal for activating the XO system 118 and for returning the XO system 118 to the standby mode. The controller 216 has an adjust output to adjust the capacitance values of the first and second adjustable capacitors C1 and C2. The controller 216 has one or more additional outputs for adjusting operation of the amplifier core 210. The controller 216 may also have one or more additional outputs for enabling various blocks and for controlling various parameters of the amplifier core 210 as further described herein.

In the illustrated embodiment, the controller 218 is shown receiving TMP providing an indication of the temperature. The controller 218 may use the indication of temperature to invoke an AGC process, such as when the temperature has changed by a certain amount. Alternatively, the AGC process may be performed upon each startup of the crystal oscillator 203. Alternatively, the transceiver 100 and/or the electronic system may invoke the AGC process based on temperature or other operating conditions. In any case, the AGC process may be invoked to adjust the level of the oscillating signal on XI or XO.

The crystal amplifier 202 sustains oscillation of the crystal 120 by generating the appropriate level of negative resistance between XO and XI (coupled across the crystal 120) to develop an oscillating signal. The oscillating signal generally has a sinusoidal waveform, which is provided to an input of a squaring buffer 218. The squaring buffer 218 converts the oscillating signal on XI (or, alternatively, XO) to a squarewave clock signal CK, which is provided to an input of a level shifter 220. The level shifter 220 adjusts the voltage level of CK and provides a corresponding clock signal CLK to an input of an inverting, selection, and buffering circuit 222. The inverting, selection, and buffering circuit 222 incorporates multiple inverters, multiplexers (MUXes), and buffers or the like for providing multiple clock signals and inverted clock signals based on CLK. The inverting, selection, and buffering circuit 222 may also convert one or more clock signals or inverted clock signals from single-ended to differential format. The controller 216 has corresponding outputs for selecting between each clock signal or its inverted version. One or more of the selected clock signals may be provided directly to selected portions of the transceiver 100. One or more of the selected clock signals may also be provided to other circuitry (not shown) within the clock system 116 for further processing, such as clock synthesizers or the like (not shown), for providing one or more modified clock signals (e.g., changes of one or more of frequency, duty cycle, amplitude, etc.) for use by other portions of the transceiver 100. The particular clock signals or uses thereof are not further described herein.

FIG. 3 is a schematic and block diagram of the crystal amplifier 202 implemented according to one embodiment of the present invention shown coupled to the crystal 120 and the controller 216, and further including a select circuit 302, a level detector 304, and a memory 310. The select circuit 302 is shown as a multiplexer (MUX) or the like, having a pair of inputs for selecting between the XO and XI (i.e., between the amplifier output node 204 and the amplifier input node 206) based on a select input receiving a select signal SEL from the controller 216. The select circuit 302 provides a selected output to an input of the level detector 304. The level detector 304 may be implemented as a peak detector, an amplitude detector, a signal level detector, such as for determining the root-mean-square (RMS) level of an input voltage level, etc. The level detector 304 provides a level detect value LD to an input of the controller 216. It is noted that the level detector 304 may incorporate the select circuit 302 and receive SEL for selecting between XO or XI. In one embodiment, the level detector 304 asserts LD when a level of a selected one of the amplifier input and ouptut nodes XI or XO reaches a level threshold. One or more threshold values TH1, TH2, etc., may be defined. In one embodiment, the memory 310 is accessible by the controller 216 and may be provided to store at least one threshold value, which is also accessible by the level detector 304 via a signal L_TH.

The amplifier core 210 includes an adjustable current source 306, a P-channel transistor P1, an N-channel transistor N1, a decoupling capacitor CD, a bias resistor RB, a first resistor R1 and a second resistor R2. P1, N1 and RB form an amplifier 313 of the amplifier core 210. The current source 306 is coupled to a source voltage VDDA, and provides a core bias (CB) current to a source node 308 developing a source voltage VS. The current source 306 includes an adjust input receiving a value CBA from the controller 216 for adjusting the level the core bias current. The source node 308 is coupled to a one terminal of R1 and to one terminal of the decoupling capacitor CD, in which the other terminal of the capacitor CD is coupled to GND. The other terminal of R1 is coupled to a first core node 312 further coupled to a source terminal of P1, having a drain terminal coupled to the amplifier output node 204 and having a gate terminal coupled to the amplifier input node 206. The amplifier output node 204 is further coupled to a drain terminal of N1, having its gate terminal coupled to the amplifier input node 206 and its source terminal coupled to a second core node 314 further coupled to one terminal of R2. The other terminal of R2 is coupled to GND. The bias resistor RB is coupled between the amplifier output node 204 and the amplifier input node 206.

It is noted that each of the transistors described herein, including P1 and N1, are one of at least two different conductivity types, such as either N-type (e.g., N-channel) or P-type (e.g., P-channel). Each transistor includes two current terminals (e.g., drain and source terminals), and a control terminal (e.g., gate terminal). In the illustrated configuration, each transistor may be configured as a MOS transistor or a FET or the like, including any one of various configurations of MOSFETs and the like. For example, the N-type transistors may be NMOS transistors or NFETs, and the P-type transistors may be PMOS transistors or PFETs.

In the illustrated embodiment, the resistors R1 and R2 are shown as adjustable resistors. In an alternative embodiment, at least one of the resistors R1 and R2 may be fixed. In another alternative embodiment, either one of the resistors R1 and R2 may be eliminated (e.g., replaced by a short). Also, R1 and R2 may have the same resistance, or may have different resistances. The controller 216 provides a first adjust value R1A to an adjust input of R1 and provides a second adjust value R2A to an adjust input of R2. The controller 216 may be implemented as a digital state machine or the like in which adjustments of the crystal amplifier 202 are made by providing and/or updating changing digital code values to various components. Although the controller 216 is shown embodied within a single block within the XO system 118, control functions may be distributed at various locations within the XO system 118 and/or within the clock system 116 and/or the transceiver 100. One or more of the digital code values as described herein may be adjustable or otherwise programmable within a corresponding programmable memory or the like (not shown). CBA may be a digital code value provided to the current source 306, in which the controller 216 adjusts CBA to adjust the core bias current provided to the source node 308 accordingly. Likewise, the controller 216 may provide two separate digital code values, including R1A for adjusting the resistance of R1 and R2A for adjusting the resistance of R2. The controller 216 is shown receiving ACT and TMP.

In an alternative embodiment, a set of fuses or the like may be used for setting or adjusting the R1A and R2A values, such as by selectively blowing one or more fuses provided on the IC. The fuses may be provided separately or as part of the controller 216. One limitation of fuses is that once the fuses are blown for a given chip, the corresponding values may not be further adjustable. For a given configuration with a selected crystal, this may be sufficient since the resistance values of R1 and R2 do not need to change for the selected crystal. Programmable code values from the controller 216 or from some other source, including an external interface, however, provides greater flexibility by allowing the resistance values of R1 and R2 to be programmed and/or adjusted at any time, such as for a different crystals and/or different configurations or electronic systems.

Operation of the crystal amplifier 202 of the crystal oscillator 203 is now briefly described. The crystal amplifier 202 is initially placed into a standby mode and remains in standby while ACT is negated. When ACT is asserted to initiate startup, the controller 216 performs a startup routine or process to initialize oscillation. The startup process is not further described, but generally includes starting with a high value of core bias current via CBA until oscillation is achieved. Once oscillation is determined to be achieved, the controller 216 adjusts CBA to reduce the core bias current to a steady state level. In one embodiment, the steady state current level of the core bias current is known. For example, the controller 216 may store a digital steady state (SS) value in the memory 310 and adjust CBA to the SS value for steady state operation. The memory 310 may be a read-only memory (ROM) or the like. Alternatively, the memory 310 may be a random access memory (RAM) or the like for determining and storing one or more different SS values during operation. In one embodiment, the controller 216 performs an automatic gain control (AGC) process or the like to determine the steady state level of the core bias current that achieves a signal level at XI or XO, determines the corresponding SS value, and stores the SS value into the memory 310 for future use.

The controller 216 may perform the AGC process upon each startup, such as for determining an adjusted SS value for each operating session, or in response to another stimulus or event, such as a temperature change. The controller 216 may perform the AGC process in response to a change of temperature, such as when TMP indicates that the temperature has changed by a certain amount. For example, at certain increments of temperature change, such as 10, 20, 30, etc., degree increments or the like, the AGC process may be re-run to adjust the core bias current to return the signal amplitude back to a target value. In one embodiment, the controller 216 asserts SEL to select XI or XO and monitors the signal level via LD provided by the level detector 304 while adjusting CBA. When the level is at a predetermined target level determined by a selected threshold value (e.g., a selected one of TH1, TH2, etc., provided via L_TH), the level detector 304 asserts LD indicating that the signal level has reached the threshold, the controller 216 determines the steady state level for the core bias current.

It has been observed that as the temperature rises, the amplitude of the oscillating signal, such as on XI, decreases. In order to optimize operating parameters, such as phase noise, PSR, and reverse PSR performance, the amplitude of the oscillating signal developed by the crystal oscillator 203 should be maintained, which in turn results in the need to run the AGC process when the temperatures changes by a certain amount. Even if the amplitude is maintained the change in temperature changes the operation point of the amplifier devices, which leads to changes in the distortion level of the amplifier devices in turn changing their output impedance over the oscillation period. These changes lead to a frequency change. The resistors R1 and/or R2 add resistive degeneration to the crystal amplifier core 210, which minimizes the amount of distortion and frequency shift as compared to a corresponding amplifier core without the degeneration resistors R1 and R2. As temperature changes causing the amplitude of the oscillating signal to change, the AGC process may be used to adjust the core bias current to re-adjust the amplitude of the oscillating signal back to the target value. An increase of the core bias current, however, also contributes to distortion of the oscillating signal. Changes in temperature also have an effect on the operation of the crystal 120.

The resistors R1 and/or R2 add resistive degeneration to the crystal amplifier core 210, which minimizes the amount of distortion and frequency shift as compared to a corresponding core without the degeneration resistors R1 and/or R2. The addition of the degeneration resistors R1 and/or R2 tends to reduce the gain of the amplifier core 210, but may also cause a degradation of certain operating parameters, such as phase noise, PSR, and reverse PSR. The core bias current may be slightly higher at any given temperature to achieve the desired amplitude of the oscillating signal as compared to a conventional configuration without the degeneration resistors R1 and/or R2. As the resistive values of R1 and R2 increase, the amount of distortion decreases. Yet higher resistive values of R1 and R2 also reduces the gain of the crystal amplifier core 210 along with a corresponding degradation of the operating parameters. In this manner, the resistive values of R1 and R2 may be empirically determined for a given configuration to optimize the trade-off between distortion and frequency shift reduction and degradation of operating parameters.

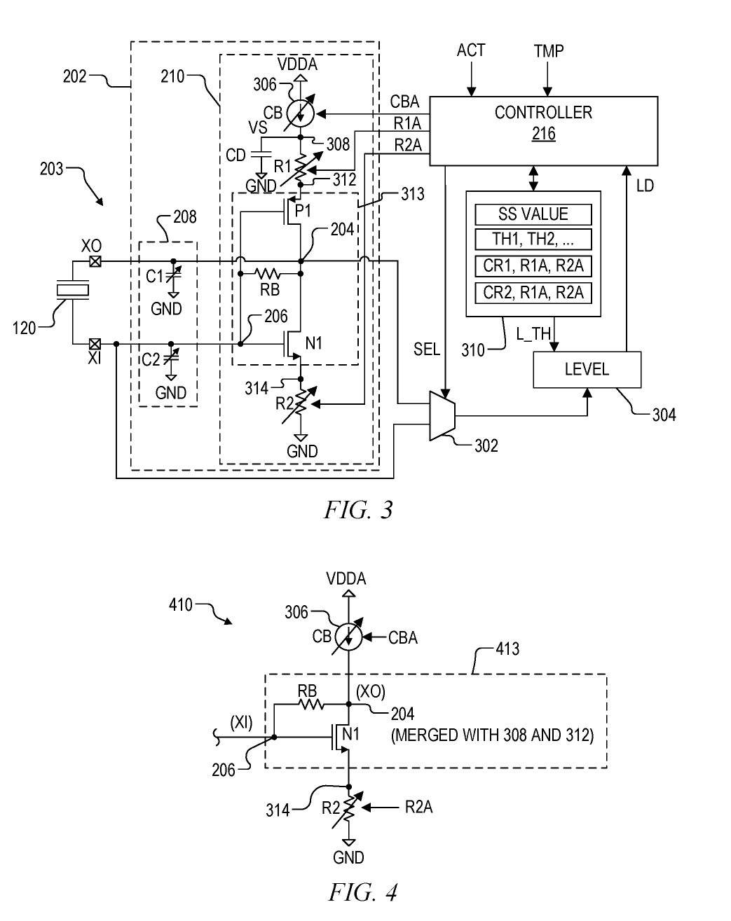

FIG. 4 is a schematic diagram of an alternative amplifier core 410 that may replace the amplifier core shown in FIG. 3. The amplifier core 210 may be implemented according to a CMOS configuration including the P-channel transistor P1 and the N-channel transistor N1, along with the decoupling capacitor CD, the bias resistor RB, and the degeneration resistors R1 and R2 (or at least one of the resistors R1 and R2). The amplifier core 410 is implemented according to an NMOS configuration in which P1, CD, and R1 are eliminated. The amplifier 313 is replaced by an amplifier 413 including N1 and RB. The current source 306 is provided for both configurations. For the amplifier core 410, however, nodes 308 and 312 are effectively merged into node 204 since P1 and R1 are eliminated, and the current source 306 provides the core bias current directly to the amplifier output node 204. RB remains coupled between nodes 204 and 206 in the same manner. Operation is substantially similar and only one degeneration resistor, shown as R2, is provided.

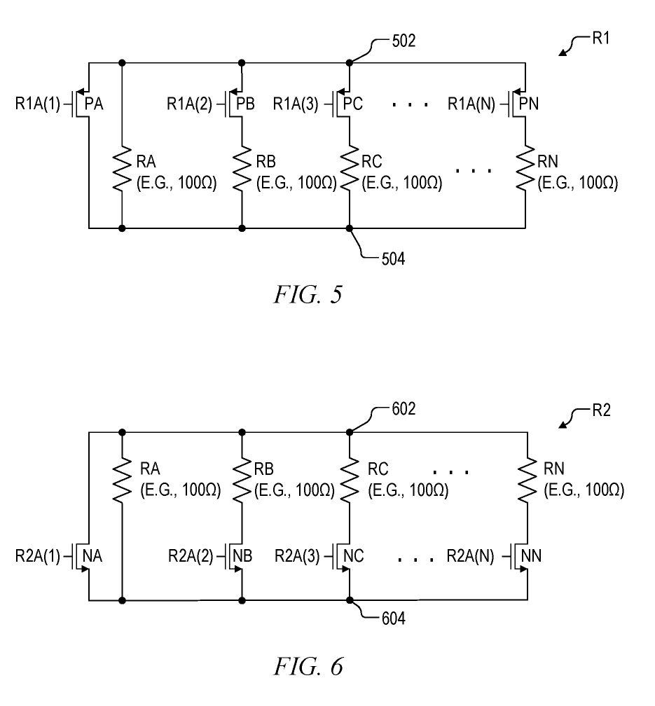

FIG. 5 is a schematic diagram of R1 implemented according to one embodiment of the present invention in which R1 is programmable or otherwise adjustable. The configuration for R2 is similar as further described below. Generally, a set of resistors RA, RB, RC, . . . , RN are coupled in parallel between a pair of terminals 502 and 504 representing the terminals of R1, which may be coupled to nodes 308 and 312, respectively, as shown in FIG. 3. A set of P-channel transistor switches PA, PB, PC, . . . , PN are provided, each coupled to a corresponding one of the resistors RA-RN for selectively inserting the corresponding resistor into the circuit. Each of the resistors RA-RN may have the same resistance; for example, each may be 100Ω as shown. A corresponding set of bits R1A(1), R1A(2), R1A(3), . . . , R1A(N) are provided by the controller 216 to control the set of transistor switches PA-PN, respectively, to selectively insert or remove a corresponding one of the resistors RA-RN, to thus control the overall resistance of the adjustable resistor. Each of the bits R1A(1)-R1A(N) is negated high to turn the corresponding switch off or asserted low to turn the corresponding switch on. The first resistor RA and the first transistor switch PA are coupled in parallel between the terminals 502 and 504. Each of the remaining transistor switches PB-PN is coupled in series with a corresponding one of the resistors RB-RN between the terminals 502 and 504 as shown. Thus, RB is coupled in series with transistor switch PB and controlled by bit R1A(2), RC is coupled in series with transistor switch PC and controlled by bit R1A(3), . . . , and RN is coupled in series with transistor switch PN and controlled by bit R1A(N).

N may be zero (0) or any positive integer. A value of zero denotes the case in which R1 may be a fixed-value resistor that is not adjustable. In certain configurations, for example, the resistance may be known in advance and the semiconductor chip or IC manufactured accordingly. A value of N=1 means selectively inserting a single resistor or shorting the resistor terminals 502 and 504 together. A value of N=2 provides the ability to have up to two of the resistors coupled in parallel between the resistor terminals 502 and 504, a value of N=3 provides the ability to have up to three of the resistors coupled in parallel between the resistor terminals 502 and 504, and so on.

In operation, the controller 216 asserts R1A(1) low to turn on transistor switch PA to short the terminals 502 and 504 together resulting in the lowest total resistance RT of RT=0Ω. In this case, the remaining switches PB-PN are turned off so that the resistors RB-RN are removed, and RA is shorted by the switch PA. The controller 216 negates all of the bits R1A(1)-R1A(N) to turn off all of the transistor switches PA-PN to remove the resistors RB-RN other than RA, so that only RA remains coupled between the terminals 502 and 504. This results in the highest total resistance being that of the resistance of RA, or RT=RA. In one embodiment, RA=100Ω so that the highest resistance for the adjustable resistors R1 is loon. The controller 216 turns off transistor switch PA and turns on one or more of the transistor switches PB-PN to program successively lower total resistance values as additional resistors are placed in parallel. If only transistor switch PB is turned on, then RA and RB are placed in parallel with each other for a resistance of RA∥RB=RA*RB/(RA+RB). If RA=RB=100Ω, then the total resistance is 50Ω when only transistor switch PB is turned on. In a similar manner, if only transistor switches PB and PC are turned on, then the total resistance RT is determined as a parallel combination of RA, RB, and RC, or RT=RA∥RB∥RC. If each of the resistors is 100Ω, then RT=˜33Ω. For an embodiment in which RA=RB=RC, . . . , =RN=100Ω, then RT is selected from the set of resistances 100Ω, 50Ω, 33Ω, 25Ω, 20Ω, . . . , 0Ω.

It is noted that the configuration shown in FIG. 5 is only one of many possible different switched resistor configurations. For example, a switched resistor ladder (not shown) or the like allows the selection of any number of resistors to be coupled in series, in parallel, or any suitable combination thereof. The included resistors may have the same resistance value, or may be varied according to any suitable mathematical progression, such as geometric progression, binary progression, etc. In a general case, the switched resistive configuration provides a suitable range of resistance values between a minimum resistance and a maximum resistance with any desired resistance adjustment granularity or any number of total resistance values. Although an increased number of resistors and switches provide a greater number of possible resistance values, it may also be desired to limit the number of switches to limit the number of bits provided by the controller 216.

FIG. 6 is a schematic diagram of R2 implemented according to one embodiment of the present invention in which R2 is programmable or otherwise adjustable. The configuration of R2 is substantially similar, operates in the same manner, and may include a copy of the same resistors RA-RN as shown, although R2 may include an array of different-valued resistors. The transistor switch NA is coupled in parallel with resistor RA between resistor terminals 602 and 604, which may be coupled to node 314 and GND, respectively, as shown in FIGS. 3 and 4. For R2, however, the transistor switches PA-PN are replaced by corresponding N-channel transistor switches NA-NN, and each of the transistor switches NB-NN are positioned below the corresponding resistors RB-RN, in which the resistors RB-RN are instead coupled to the upper resistor terminal 602 and the transistor switches NB-NN are instead coupled to the lower resistor terminal 604. The transistor switches NA-NN are controlled by corresponding bits R2A(1)-R2A(N), respectively, in similar manner.

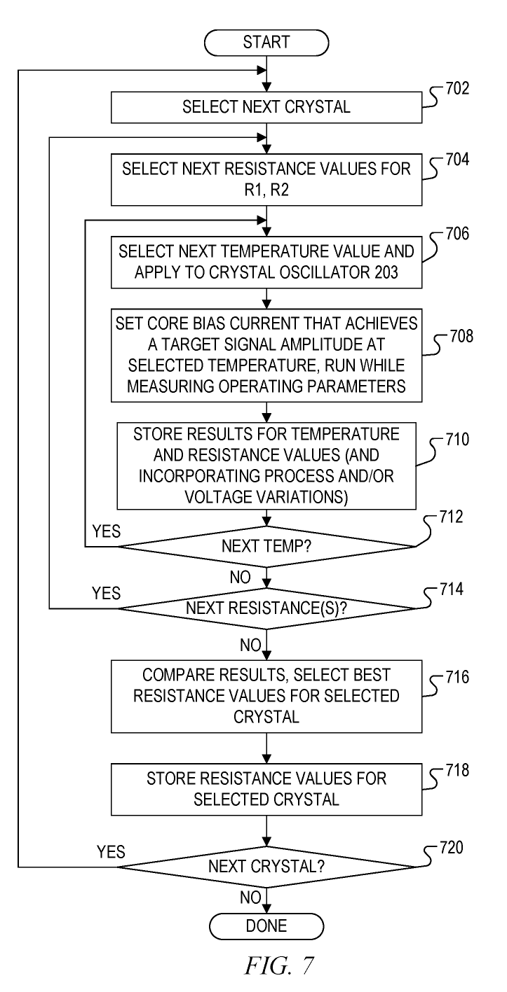

FIG. 7 is a flowchart diagram of a simplified test procedure of the crystal oscillator 203 for determining resistance values for the degeneration resistors R1 and R2 of the amplifier core 210 for one or more different crystals according to one embodiment of the present invention. Operation is substantially the same when only one degeneration resistor is included, such as R2 for the amplifier core 410 according to the NMOS configuration. One or more semiconductor chips incorporating the transceiver 100 may be placed into a test apparatus (not shown) or the like for performing various tests including testing of the crystal oscillator 203. Other test procedures performed for other purposes are not further described. The illustrated test procedure is simplified in that it mostly includes testing for different temperatures for different crystals. It is understood, however, that other variations can be incorporated into the test procedure, including process variations and voltage variations. Process variations can be incorporated into the test procedure by performing the same test on multiple different chips at a time and/or over time. Voltage variations can be incorporated into the test procedure by performing the same test at different source voltages within an allowable or expected range of source voltages. For example, the same or similar test may be performed for each of one or more chips at a minimum source voltage, and again at a maximum source voltage, and possibly again at a normal source voltage. Alternatively, the same or similar test may be performed for each of one or more chips at multiple source voltages within the allowable or expected range of source voltages.

At a first block 702, the “next” crystal (or crystal type) to be tested is selected and an exemplary crystal is coupled to the crystal amplifier 202. The test procedure may be performed for one or more crystals in which corresponding resistance values may be stored for each crystal. At next block 704, the “next” set of resistance values are selected for R1 and R2. Although the resistance values may be evaluated in any order, in one embodiment a resistance value of 0Ω may first be selected for R1 and R2 since operating parameters achieved for non-zero resistances are generally compared with a configuration with 0 resistance. In one embodiment, the same resistance value is selected for R1 and R2. In another embodiment, different resistance values between R1 and R2 may be tested, although the test procedure may be modified to include additional testing for resistance offsets. Once selected, the R1A and R2A values are asserted by the controller 216 to adjust R1 and R2 for test operation.

At next block 706, the next temperature value is selected for evaluation and applied to the crystal oscillator. Although the temperature level may be varied by a predetermined temperature increment (e.g., 10° C., 20° C., 30° C., etc.) between a minimum temperature to a maximum temperature from one iteration to the next, a single temperature value may be selected to represent a relatively large temperature range. As an example, in one embodiment only three (3) different temperatures are selected, including a COLD temperature below a standard room temperature, a ROOM temperature representing a normal operating temperature, and a HOT temperature representing temperatures above the normal operating range. In addition, the test may incorporate the same test for the same crystal on different chips (process variations) and/or different source voltages (voltage variations).

At next block 708, the core bias current is adjusted and set by CBA to achieve the target signal amplitude of the oscillating signal at the selected temperature level. For example, the AGC process performed by the XO system 118 may be used by adjusting the core bias current generated by the current source 306 until the signal level on XI (or XO) is at the target amplitude. Alternatively, the test apparatus may perform the AGC process by adjusting CBA until the amplitude of the oscillating signal on XI (or XO) is at the target level. Then the crystal oscillator 203 is run while the operating parameters of the crystal oscillator 203 are measured. Exemplary operating parameters may include phase noise, power supply rejection (PSR), reverse PSR, frequency, among others. At next block 710, the measured operating parameters are stored for the given temperature and resistance values. At block 710, the stored results may include process and/or voltage variations.

At next block 712, it is queried if another temperature value is to be evaluated. If so, then operation returns to block 706 and the next temperature value is selected and applied to the crystal oscillator 203. Then blocks 708 and 710 are repeated for the new temperature value. For example, the first iteration may be performed for a COLD temperature, the next iteration may be performed for a ROOM temperature, and a final iteration may be performed for a HOT temperature. In each case, the core bias current is adjusted to ensure the target signal amplitude, and the crystal oscillator 203 is operated at the new temperature while the operating parameters are measured and stored. The test procedure may further incorporate process and voltage variations as previously described.

Once the operating parameters have been measured for a selected set of resistance values for each of the temperature values, operation proceeds to block 714 to query whether the tests are to be repeated for the next set of resistance values. A first iteration may be performed for resistances of 0Ω for purposes of comparison, and then the resistance values may be incrementally increased for each iteration. If additional resistances are to be evaluated, then operation returns to block 704 to select the next resistance values for R1 and R2 and the operations at blocks 706, 708, 710 and 712 are performed again for the next set of resistance values. It is noted that certain combinations of crystals, temperatures, resistances, and/or voltages may cause improper operation, such as undesirable saturation of one or more components or the like. If known beforehand, then the particular iteration may be skipped, or else improper operation is determined at block 708 so that the corresponding results may not be stored as not being an acceptable combination.

Once the operating parameters have been measured for each set of resistance values for each of the temperature values (and may further includes process and/or voltage variations), operation proceeds to block 716 in which the stored results are compared for selecting the “best” set of resistance values for the selected crystal. In one embodiment, for example, deviations of the operating parameters are evaluated and compared for each set of resistance values over the temperature ranges, voltage ranges and/or over different semiconductor chips (process variations). The operating parameters may include deviations of phase noise, PSR, reverse PSR, and frequency. The best set of resistance values may be considered to be the maximum resistance values in which any deviations of each of operating parameters is within predetermined acceptable specification ranges. For example, an acceptable range may include up to 1 decibel (dB) degradation of phase noise and up to 2 dB of PSR degradation for each temperature value/range tested, and may further incorporate process variations and voltage variations. The maximum set of resistance values that meet the designated degradation ranges may be selected.

At next block 718, the selected resistance values are stored for the selected crystal. For example, the memory 310 may include space for storing R1A and R2A values for each of one or more crystals, shown as crystal CR1, CR2, etc. Although two values may be stored for each of one or more crystals or crystal types, a single resistor value may be stored instead for each crystal or crystal type when both resistors are programmed to have the same resistance. Operation then proceeds to block 720 to query whether another crystal is to be evaluated. If so, operation loops back to block 702 in which the next crystal is selected, and the entire test procedure is (or set of test procedures are) performed for the next crystal. Once each crystal of interest has been evaluated and corresponding resistance values stored, operation is completed.

It is noted that for embodiments in which fixed resistors are used for R1 and/or R2 (or just R2 for NMOS configuration), the IC or semiconductor chip may be manufactured with selected resistance values for R1 and/or R2 (CMOS) or R2 (NMOS).

The present description has been presented to enable one of ordinary skill in the art to make and use the present invention as provided within the context of particular applications and corresponding requirements. The present invention is not intended, however, to be limited to the particular embodiments shown and described herein, but is to be accorded the widest scope consistent with the principles and novel features herein disclosed. Many other versions and variations are possible and contemplated. Those skilled in the art should appreciate that they can readily use the disclosed conception and specific embodiments as a basis for designing or modifying other structures for providing the same purposes of the present invention without departing from the spirit and scope of the invention.

1. A crystal amplifier for driving a crystal to oscillate at a resonant frequency, comprising:
an amplifier input node and an amplifier output node for coupling across the crystal;
an amplifier having an input coupled to said amplifier input node and having an amplifier output current path coupled to said amplifier output node;
at least one degeneration resistor coupled in series with said amplifier output current path; and
a current source that provides a core bias current through said amplifier output current path and through said at least one degeneration resistor to a reference node.

2. The crystal amplifier of claim 1, wherein each of said at least one degeneration resistor has a resistance that can be selected based on a crystal type.

3. The crystal amplifier of claim 1, wherein each of said at least one degeneration resistor has a resistance that minimizes a frequency shift of an oscillating signal of the crystal over an operating temperature range while maintaining at least one operating parameter within predetermined operating limits.

4. The crystal amplifier of claim 1, wherein each of said at least one degeneration resistor is adjustable, further comprising a controller that selects a resistance of each of said at least one degeneration resistor.

5. The crystal amplifier of claim 4, further comprising a memory for storing at least one digital value accessible by said controller for selecting said resistance of each of said at least one degeneration resistor.

6. The crystal amplifier of claim 4, wherein each of said at least one degeneration resistor comprises a plurality of resistors and a corresponding plurality of switches coupled between first and second resistor terminals, and wherein said controller controls said plurality of switches for selecting said resistance.

7. The crystal amplifier of claim 6, wherein said controller comprises a digital state machine.

8. The crystal amplifier of claim 6, wherein:
said plurality of resistors and said corresponding plurality of switches comprise:
a first resistor coupled between said first and second resistor terminals;
a first switch coupled between said first and second resistor terminals; and
at least one resistor switch pair, each comprising an additional resistor and an additional switch coupled in series between said first and second resistor terminals; and
wherein said controller turns off said first switch and each said additional switch to select said first resistor, turns on only said first switch to short said first and second resistor terminals together, and turns off said first switch and turns on at least one of said each additional switch to couple at least one of said corresponding additional resistor in parallel with said first resistor.

9. The crystal amplifier of claim 1, wherein:
said at least one degeneration resistor comprises:
a first degeneration resistor having a first terminal coupled to an output of said current source and having a second terminal; and
a second degeneration resistor having a first terminal coupled to said reference node and having a second terminal; and
wherein said amplifier comprises:
a P-channel transistor having a source terminal coupled to said second terminal of said first degeneration resistor, having a drain terminal coupled to said amplifier output node, and having a gate terminal coupled to said amplifier input node;
a bias resistor coupled between said amplifier input node and said amplifier output node; and
an N-channel transistor having a drain terminal coupled to said amplifier output node, having a source terminal coupled to said second terminal of said second degeneration resistor, and having a gate terminal coupled to said amplifier input node.

10. The crystal amplifier of claim 1, wherein:
said amplifier comprises:
an N-channel transistor having a drain terminal coupled to an output of said current source, having a gate terminal coupled to said amplifier input node, and having a source terminal;
a bias resistor coupled between said amplifier input node and said amplifier output node; and
wherein said at least one degeneration resistor includes a degeneration resistor having a first terminal coupled to said source terminal of said N-channel transistor and having a second terminal coupled to said reference node.

11. An electronic circuit, comprising:
a crystal having a first terminal and a second terminal; and
a crystal amplifier for driving said crystal to oscillate at a resonant frequency, said crystal amplifier comprising:
an amplifier input node coupled to said first terminal of said crystal and an amplifier output node coupled to said second terminal of said crystal;
an amplifier having an input coupled to said amplifier input node and having an amplifier output current path coupled to said amplifier output node;
at least one degeneration resistor coupled in series with said amplifier output current path; and
a current source that provides a core bias current through said amplifier output current path and through said at least one degeneration resistor to a reference node.

12. The electronic circuit of claim 11, wherein each of said at least one degeneration resistor has a resistance that minimizes a frequency shift of an oscillating signal of said crystal over an operating temperature range.

13. A method of driving a crystal to oscillate at a resonant frequency, comprising:
providing an amplifier input node and an amplifier output node for coupling across the crystal;
providing an amplifier having an input coupled to the amplifier input node and having an amplifier output current path coupled to the amplifier output node;
providing at least one degeneration resistor coupled in series with the amplifier output current path; and
providing a core bias current through the amplifier output current path and through the at least one degeneration resistor to a reference node.

14. The method of claim 13, wherein said providing at least one degeneration resistor comprises providing each of at least one degeneration resistor with a resistance that can be selected based on a crystal type.

15. The method of claim 13, wherein said providing at least one degeneration resistor comprises providing at least one degeneration resistor having a resistance that can minimize a frequency shift of an oscillating signal of the crystal over an operating temperature range while maintaining at least one operating parameter within predetermined operating limits.

16. The method of claim 13, wherein:
said providing at least one degeneration resistor comprises providing at least one adjustable degeneration resistor; and
further comprising providing a controller that selects a resistance of each degeneration resistor.

17. The method of claim 16, further comprising storing at least one digital value accessible by the controller for selecting the resistance of each degeneration resistor.

18. The method of claim 13, wherein said providing at least one degeneration resistor comprises providing a plurality of resistors and a corresponding plurality of switches coupled between first and second resistor terminals, and further comprising controlling the plurality of switches for selecting a resistance between the first and second resistor terminals.

19. The method of claim 13, further comprising selecting a resistance of each of the at least one degeneration resistor to minimize a frequency shift of an oscillating signal of the crystal over an operating temperature range while maintaining phase noise degradation within an allowable range.

20. The method of claim 13, further comprising selecting a resistance of each of the at least one degeneration resistor to minimize a frequency shift of the oscillating signal of the crystal over an operating temperature range while maintaining degradation of power supply rejection within an allowable range.
